(19) United States
(12) Patent Application Publication
(10) Pub. No.: US 2009/0201252 A1
(43) Pub. Date: Aug. 13, 2009

(54) METHOD AND APPARATUS FOR ALPHANUMERIC DATA ENTRY USING A KEYPAD

(76) Inventor: Seok Ho Lee, Suwon-si (KR)

Correspondence Address: MCDERMOTT WILL & EMERY LLP, 600 13TH STREET, N.W., WASHINGTON, DC, 20005-3096, US

(21) Appl. No.: 11/910,573

(22) PCT Filed: Oct. 2, 2006
(86) PCT No.: PCT/KR06/03981

§ 371 Date: Oct. 3, 2007

(51) Int. Cl. G06F 3/02; H03M 11/00

(52) U.S. Cl. 345/168; 341/22

(57) ABSTRACT

A keypad for inputting alphabetical characters for use in an electronic device comprises an array of keys, each of which is assigned to one of elements of alphabetical characters. Each element is a portion of an alphabetical character and combination of the elements forms each character. The alphabetical character is produced by activation of keys to which the elements constituting the character are assigned.

### TECHNICAL FIELD

The present invention relates to a method and an apparatus for entering alphanumeric data using a keypad.

### BACKGROUND ART

With the extensive use of wireless communication devices, the communication devices are used in diverse ways, such as sending text message and accessing the Internet. Because such uses require fast entry of alphanumerical entry, various alphanumerical data or text entry methods to enter the data or text fast and conveniently have been developed.

U.S. Pat. No. 5,392,338 to Danish et al. discloses a method for entering alphanumerical characters using a conventional push button telephone system which requires activating a particular number-key once or several times until a desired letter is displayed. The method requires locating a desired letter, which is grouped among two or three other letters, on a corresponding number key. Once the corresponding number key is located, the user then activates the located key a number of times according to the position of that letter in the group of letters on the key. However, for sequential entry of two consecutive letters on the same key (for example, letters m and n, which are on key-6) the user, after entering a first letter on a key, must pause for a predefined time period to enter a subsequent letter on the same key. The pause would allow the system to recognize the sequential entry of two letters on the same key. The forced pause associated with entering letters that use the same key makes the data entry process slow, while interrupting the flow of user's input.

U.S. Pat. No. 6,847,706 to Bozorgui-Nesbat discloses a method and a keypad for alphanumeric data entry in which each key are assigned to at least one letter of an alphabetical system according to frequency of occurrence of key. The most-frequently-occurring letters—A(1), N(2), I(3), H(4), R(6), T(7), E(8), S(9)—are entered by two activation of the same key and the less-frequently occurring letters—V(1), L(2), X(3), K(4), M(6), Y(7), W(8), F(9)—are entered by activation of two different keys, first activation of each corresponding key and activation of key 5 in succession. The least frequently occurring letters—Q, U, P, C, B, G, D, J—are entered by activation of two different keys, first activation of key 5 and then activation of key pointed to by the peripheral position of that letters pointing to keys 1, 2, 3, 4, 6, 7, 8, 9. Although the forced pause is unnecessary, it is inconvenient for a user to memorize sequences of key activation for each letter and the data entry is slow.

U.S. Pat. No. 6,043,761 to Burrell discloses a way to use a twelve button telephone keypad for alphanumeric data entry in which two binary keys are used for an all capital letter mode or two binary keys for a lower-case letter mode, along with three binary keys for an upper-case letter mode, for producing full alphanumeric text, including punctuation, symbols and control. Because this method still uses short or long duration for alphanumeric data entry, it requires users' attentiveness and thereby is slow in data entry.

### DISCLOSURE

### Technical Problem

The above arrangement of characters to the array of keys still leads to a large number of unnecessary key activations, thereby increasing time of text entry.

It is an object of the present invention to provide a method and an apparatus for entering alphanumerical data on electronic devices fast and conveniently.

Another object is to provide a keypad layout where user inputs desired characters by activations of keys to which elements of characters are assigned, wherein the elements are portions of characters and combinations of the elements form alphabets and special characters.

### Technical Solution

The above objects, as well as other advantages described herein, are achieved by providing a keypad for inputting alphabetical characters for use in an electronic device. In the keypad, provided is an array of keys, each of which is assigned to one element to be used in forming a letter, number, character. Each element is a portion of an alphabetical character and a combination of the elements forms each character. The alphabetical character is produced by activation of keys to which the elements constituting the character are assigned.

The keys to which elements constituting a desired character are assigned are activated sequentially. A key is also provided for changing input modes between lower case characters, upper case characters and special characters.

In another aspect of the invention, an electronic device that functions upon receiving alphabetical character data for performing functions includes an array of keys, a memory and a microprocessor. One element of alphabetical characters is assigned to a key forming the array of keys and each element is used to construct a portion of one or more alphabetical characters. A combination of one or more elements forms each character and the alphabetical character is produced by activation of the keys to which the elements constituting the character are assigned. The memory stores a mapping table of relation between activated keys and alphabetical characters. The microprocessor generates an alphabetical character signal in response to the activation of the keys by referring to the mapping table stored in the memory.

In still another aspect of the present invention, a method for entering alphabetical characters in an electronic device is provided. Elements of alphabetical characters are determined and each of elements is a portion of an alphabetical character based on design of the alphabetical characters. The elements of alphabetical characters are assigned to an array of keys on a keypad. One or more keys corresponding to elements of alphabetical characters are activated. One or more of the elements constitutes an alphabetical character for entry of the alphabetical character. A signal for an alphabetical character corresponding to the activation of one or more keys is transmitted to the electronic device.

### ADVANTAGEOUS EFFECTS

According to the present invention, it is possible to reduce unnecessary key activations and text entry time.

It is also possible to enter alphanumerical data on electronic devices fast and conveniently.

Further, it is still possible to provide a keypad layout where user inputs desired characters by activations of keys to which elements of characters are assigned, wherein the elements are portions of characters and combinations of the elements form alphabets and special characters.

### DESCRIPTION OF DRAWINGS

The teachings of the present invention can be readily understood by considering the following detailed description in conjunction with the accompanying drawings in which:

FIG. 1 illustrates a principle of determination of the elements from alphabets;

FIG. 2 is an exemplary assignment of elements of characters to a keypad according to the present invention;

FIG. 3 is a mapping table of upper case letters of the alphabet with the elements of the characters of FIG. 1;

FIG. 4 is a mapping table of lower case letters of the alphabet with the elements of the characters of FIG. 1;

FIG. 5 is a mapping table of special characters with the elements of the characters of FIG. 1; and

FIG. 6 is a block diagram of a keypad input system for use in an electronic device of the present invention.

To facilitate an understanding of the invention, the same reference numerals have been used, when appropriate, to designate the same or similar elements that are common to the figures. Unless stated otherwise, the features shown and described in the figures are not drawn to scale, but are shown for illustrative purposes only.

### BEST MODE

Letters of the alphabet, either lower case or upper case, and special characters can be separated into a number of elements which are portions of the letters or special characters when they are written by hand. That is, an alphabet is produced by a combination of the elements for the letters of the alphabet in the same way a word is produced by combination of vowels and consonants.

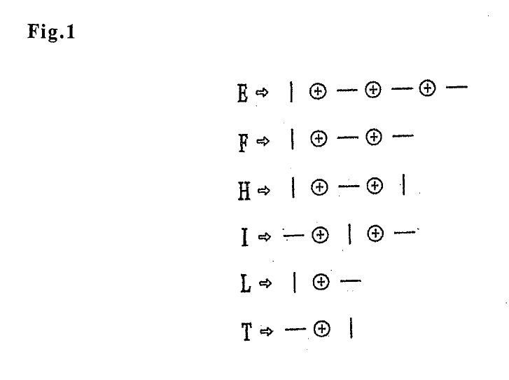

Referring to FIG. 1, upper case “E” is divided into elements “|”+“-”+“-”+“-” and upper case “F” is divided into elements “|”+“-”+“-”. Upper case “H” is divided into elements “|”+“-”+“|”. Upper case “I” is divided into elements “-”, “|” and “-”. Upper case “L” is divided into elements “|” and “-”. Upper case “T” is divided into elements “-” and “|”. The six upper case characters “E”, “F”, “H”, “I”, “L” and “T” are composed of only two kinds of elements “|” and “-” and the two elements “|” and “-” can produce six characters. If all alphabets or special character are analyzed in the same way, the ten elements, i.e. ⊂, |, ⊃, \, /, -, ∩∩, ∪∪, O, •, can produce the twenty six letters of the English alphabet and special characters.

The letters to be entered on electronic devices can be produced in the same way by providing a keypad to which the elements of alphabets in handwriting are assigned. The present invention makes use of the elements for entry of alphanumerical data on electronic devices.

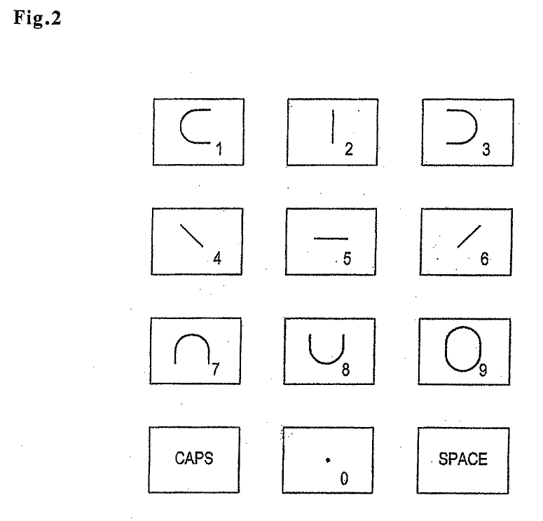

Referring to FIG. 2, in a preferred embodiment, 10 elements, i.e. ⊂, |, ⊃, \, /, -, ∩, ∪∪, O, •, are assigned to binary number keys 0-9. “CAPS” and “SPACE” are assigned to two remaining keys. It will be understood by one of ordinary skill in the art that the elements can be assigned to different keys from the layout of FIG. 2.

A keypad has twelve push-button keys for entry of alphabetic and numeric data. A key is a specified area within a user interface of an electronic device, such as a keypad, that is activated to generate a character signal representing a selected letter. The array of keys includes m rows and n columns, where m and n could be same or different integers, and m is 4 and n is 3 in the FIG. 2. Still referring to FIG. 2, a three-by-three array of keys is assigned to numbers 1-9 and the center key in the bottom row is assigned to number 0. The right key and left key in the bottom row are assigned to “CAPS” and “SPACE” respectively. Activation of “CAPS” changes the key input mode between number, upper case characters, lower case characters and punctuation marks.

In the numeric mode, a number is entered by activating a corresponding number key. In the characters and special characters input mode, the characters and special characters are entered by activation of the number keys to which elements of characters are assigned according to the following embodiment. As used herein, activation can comprise any one or combination or pressing, clicking, tapping, pointing, or otherwise, any equivalents thereof.

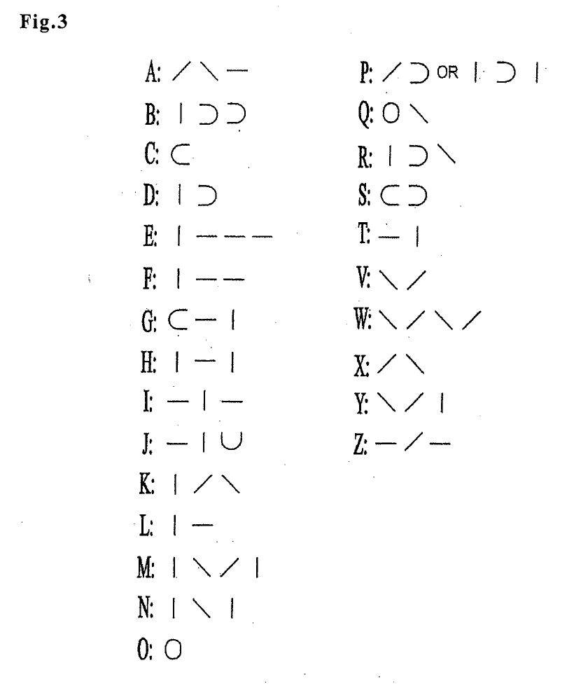

Referring to FIG. 3, upper case alphabets are divided into elements and thereby produced by activation of sequence of the elements. The present invention provides a method for entering upper case alphabetical characters based upon table of FIG. 3 as follows.

“A” is composed of “/”, “\” and “-” and produced by activations of binary number keys “6”+“4”+“5”.

“B” is composed of “|”, “⊃”, and “⊃” and produced by activations of binary number keys “2”+“3”+“3”.

“C” is composed of “⊂” and produced by activation of binary number key “1”.

“D” is composed of “|” and “⊃” and produced by activation of binary number key “2”+“3”.

“E” is composed of “|”, “-”, “-” and “-” and produced by activation of binary number key “2”+“5”+“5”+“5”.

“F” is composed of “|”, “-” and “-” and produced by activation of binary number keys “2”+“5”+“5”.

“G” is composed of “⊂”, “-” and “|” and produced by activation of binary number keys “1”+“5”+“2”.

“H” is composed of “|”, “-” and “|” and produced by activation of binary number keys “2”+“5”+“2”.

“I” is composed of “|” and produced by activation of binary number keys “2”.

“J” is composed of “-”, “|” and “∪∪” and produced by activation of binary number keys “5”+“2”+“8”.

“K” is composed of “|”, “/”, and “\” and produced by activation of binary number keys “2”+“6”+“4”.

“L” is composed of “|” and “-” and produced by activation of binary number keys “2”+“5”.

“M” is composed of “|”, “\”, “.” and “|” and produced by activation of binary number keys “2”+“4”+“6”+“2”.

“N” is composed of “|”, “\” and “|” and produced by activation of binary number keys “2”+“4”+“2”.

“O” is composed of “O” and produced by activation of binary number key “9”.

“P” is composed of “|”, “⊃” and “|” and “⊃”, and produced by activation of binary number keys “2”+“3”+“2” or “6”+“3”.

“Q” is composed of “O” and “\” produced by activation of binary number keys “9”+“4”.

“R” is composed of “|”, “⊃” and “\” and produced by activation of binary number keys “2”+“3”+“4”.

“S” is composed of “⊂” and “⊃” and produced by activation of binary number keys “1”+“3”.

“T” is composed of “-” and “|” and produced by activation of binary number keys “5”+“2”.

“U” is composed of “∪” and produced by activation of binary number key “8”.

“V” is composed of “\” and “/” and produced by activation of binary number keys “4”+“6”.

“W” is composed of “\”, “/”, “\” and “/” and produced by activation of binary number keys “4”+“6”+“4”+“6”.

“X” is composed of “/” and “\” and produced by activation of binary number keys “4”+“6”.

“Y” is composed of “\”, “/” and “|” and produced by activation of binary number keys “4”+“6”+“2”.

“Z” is composed of “-”, “/” and “-” and produced by activation of binary number keys “5”+“6”+“5”.

In a preferred embodiment, the binary number keys can be activated sequentially when different number keys are required to be activated for entry of an alphabet.

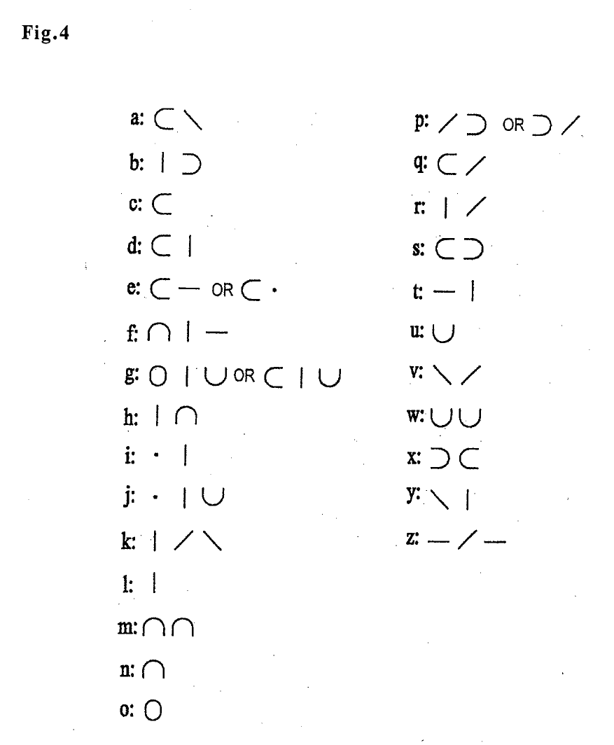

Referring to FIG. 4, a method of entering lower case alphabetical characters will be described. Activation of “CAPS” or “SPACE” key chooses entry of keys between lower case and upper case input modes.

“a” is composed of “⊂” and “\” and produced by activation of binary number keys “1”+“4”.

“b” is composed of “≡” and “⊃” and produced by activation of binary number keys “2”+“3”.

“c” is composed of “⊂” and produced by activation of binary number keys “1”.

“d” is composed of “⊂” and “|” and produced by activation of binary number keys “1”+“2”.

“e” is composed of “⊂” and “-” or “⊂” and “•” and produced by activation of binary number keys “1”+“5” or “1”+“0”.

“f” is composed of “∩”, “|” and “-” and produced by activation of binary number keys “7”+“2”+“6”.

“g” is composed of “⊂”, “|” and “∪” or “O”, “|” and “∪” and produced by activation of binary number keys “1”+“2”+“8” or “9”+“2”+“8”.

“h” is composed of “|” and “∩” and produced by activation of binary number keys “2”+“7”.

“i” is composed of “•” and “|” and produced by activation of binary number keys “6”+“2”.

“j” is composed of “•”, “|” and “∪” and produced by activation of binary number keys “0”+“2”+“8”.

“k” is composed of “|”, “/”, and “\” and produced by activation of binary number keys “2”+“6”+“4”.

“l” is composed of “|” and produced by activation of binary number key “2”.

“m” is composed of “∩” and “∩” and produced by activation of binary number keys “7”+“7”.

“n” is composed of “∩” and produced by activation of binary number keys “7”.

“o” is composed of “O” and produced by activation of binary number key “9”.

“p” is composed of “/” and “⊃” or “⊃” and “/” and produced by activation of binary number keys “6”+“3” or “3”+“6”.

“q” is composed of “⊂” and “/” and produced by activation of binary number keys “1”+“6”.

“r” is composed of “|” and “/” and produced by activation of binary number keys “2”+“6”.

“s” is composed of “⊂” and “⊃” and produced by activation of binary number keys “1”+“3”.

“t” is composed of “-” and “|” produced by activation of binary number keys “5”+“2”.

“u” is composed of “∪” and produced by activation of binary number keys “8”.

“v” is composed of “\” and “/” and produced by activation of binary number keys “4”+“6”.

“w” is composed of “∪” and “∪” and produced by activation of binary number keys “8”+“8”.

“x” is composed of “⊃” and “⊂” and produced by activation of binary number keys “3”+“1”.

“y” is composed of “\” and “|” and produced by activation of binary number keys “4”+“2”.

“z” is composed of “-” “/” and “-” and produced by activation of binary number keys “5”+“6”+“5”.

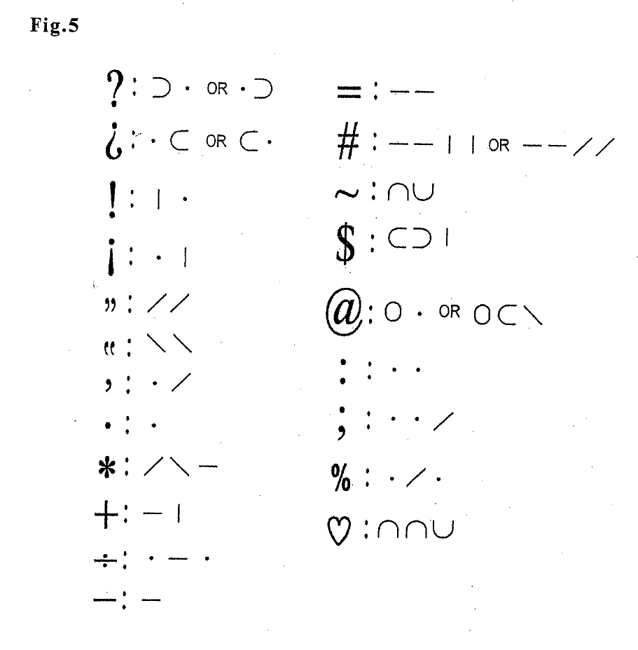

Referring to FIG. 5, a method of entering special characters will be described. Activation of “CAPS” or “SPACE” key enables an entry mode of special characters.

“?” is composed of “⊃” and “•” and produced by activation of binary number keys “3”+“0” or “0”+“3”.

“?” is used upside down at the front of a sentence in Spanish, is composed of “•” and “⊂” and can be produced by activation of binary number keys “0”+“1” or “1”+“0”.

“!” is composed of “|” and “•” a produced by activation of binary number keys “2”+“0”.

“!” is also used upside down at the front of a sentence in Spanish, and produced by activation of binary number keys “0”+“2”.

““” is composed of “\” and “\” and produced by activation of binary number keys “4”+“4”.

“”” is composed of “/” and “/” produced by activation of binary number keys “6”+“6”.

“,” is composed of “•” and “/” and produced by activation of binary number keys “0”+“6”.

“.” is composed of “•” and produced by activation of binary number key “ ”.

“*” is composed of “/”, “\” and “-” and produced by activation of binary number keys “6”+“4”+“5”.

“+” is composed of “-” and “|” produced by activation of binary number keys “5”+“2”.

“÷” is composed of “•”, “-” and “•” and produced by activation of binary number keys “0”+“5”+“0”.

“-” is composed of “-” and produced by activation of binary number keys “5”.

“=” is composed of “-” and “-” and produced by activation of binary number keys “5”+“5”.

“#” is composed of “-”, “-”, “|” and “|” or “-”, “-”, “/”, and “/” and produced by activation of binary number keys “5”+“5”+“2”+“2” or “5”+“5”+“6”+“6”.

“˜” is composed of “∩” and “∪” and produced by activation of binary number keys “7”+“8”.

“$” is composed of “⊂”, “⊃” and “|” and produced by activation of binary number keys “1”+“3”+“2”.

“♡” is composed of “∩”, “∩” and “∪” and produced by activation of binary number keys “7”+“7”+“8”.

“@” is composed of “O” and “•” or “O”, “⊂” and “\” and produced by activation of binary number keys “9”+“0” or “9”+“1”+“4”.

“:” is composed of “•” and “•” and produced by activation of binary number keys “0”+“0”.

“;” is composed of “•”, “•” and “/” and produced by activation of binary number keys “0”+“0”+“6”.

“%” is composed of “•”, “/”, and “•” and produced by activation of binary number keys “0”+“6”+“0”.

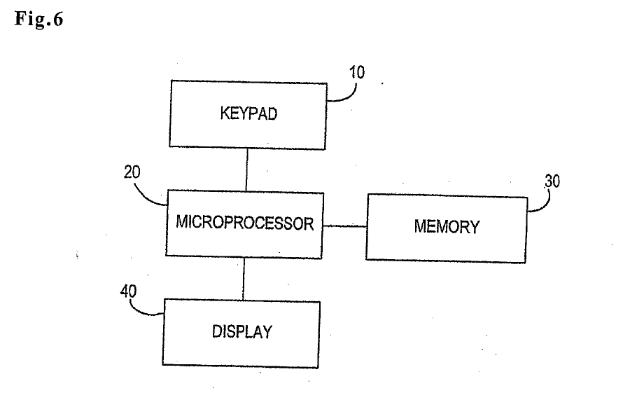

Referring to FIG. 6, in a preferred embodiment, a keypad system that may be used in an electronic device, such as a cellular phone, comprises a keypad 10, a microprocessor 20, a memory 30 and a display 40. The microprocessor 20 detects activation of a key in a keypad 10 that are assigned to one of the elements of the alphabet. In response to activation of one or more keys in the keypad 10 sequentially, the microprocessor 20 generates a letter signal referring to a mapping table between sequence of elements and letters or punctuation marks stored in the memory 30 as shown in FIGS. 3-5. The letter signal is sent to, and displayed on the display 40. An operating program that is stored in the microprocessor 20 is configured to accept input from the keypad 10 and to find appropriate letters or special characters corresponding to activated elements based on the mapping table stored in the memory 30.

If, for example, a user would like to input a word “bye”, the “CAPS” or “SPACE” key is pushed for changing the input mode into lower case. Then, number “2” and “3” keys in the keypad 10 are pushed sequentially. The letter “b” will be displayed on the display 40 upon pushing of number “2” and “3” keys. In a preferred embodiment, if any letter is formed by input of a combination of keys, any additional input of number keys does not affect pre-formed letter, here “b”. Number keys “4” and “2” are pushed sequentially for an input of the letter “y” and number keys “1” and “5” are pushed for an input of the letter “e”. As a result, “bye” is inputted into the electronic device and displayed on the display 40. The user, as a result, can enter the word “bye” fast and conveniently, without a forced pause to enter a character that is also assigned to the pre-pushed key.

It should be noted that the present invention has been described principally in conjunction with a cellular phone having alphanumeric keys for entering alphabetic characters and numerals, and special characters for entering one or more variants of the alphabetic characters. The present invention, in general, is applicable to an electronic device having a keypad containing a plurality of keys, wherein the keys are used to enter messages or information. The electronic device can be a land-line telephone, a game console, a hand-held computer, a personal digital assistant, audio-visual device remote controls, security systems, microwave ovens, automatic teller machines, cash registers, calculators and the like.

Although various embodiments that incorporate the teachings of the present invention have been shown and described in detail herein, those of ordinary skill in the art can readily devise other and varied embodiments and the scope of the invention is to be determined by the claims that follow.

1. A keypad for inputting alphabetical characters for use in an electronic device, comprising:
an array of keys, to each of which is assigned one of elements of alphabetical characters, each element being a portion of an alphabetical character, combination of the elements forming each character, wherein the alphabetical character is produced by activation of keys to which the elements constituting the characters are assigned.

2. The keypad of claim 1, wherein one or more of the keys to which the elements constituting the character are assigned are activated sequentially.

3. The keypad of claim 1, wherein special characters are produced by activation of the keys to which the elements in combination constituting the characters are assigned.

4. The keypad of claim 1, wherein the array of keys includes a key for changing input modes between lower case characters, upper case characters and special characters.

5. An electronic device that functions upon entry of alphabetical character data, the device comprising:
an array of keys, each of which is assigned to one of elements of alphabetical characters, each element being a portion of alphabetical characters, combination of the elements forming each character, wherein the alphabetical character is produced by activation of keys to which the elements constituting the character are assigned;
a memory for storing a mapping table of relation between activated keys and alphabetical characters; and
a microprocessor for generating an alphabetical character signal in response to activation of keys referring to the mapping table stored in the memory.

6. The device of claim 6, further comprising:
a display to display the alphabetical character generated by the microprocessor.

7. A method for entering alphabetical characters in an electronic device, the method comprising:
determining elements of alphabetical characters each of which is a portion of an alphabetical character based on design of the alphabetical characters;
assigning the elements of alphabetical characters to an array of keys on a keypad;
activating one or more keys corresponding to elements of alphabetical characters which constitutes an alphabetical character for entry of the alphabetical character; and
transmitting a signal to the electronic device corresponding to an alphabetical character upon activation of one or more of the keys.

8. The method of claim 8, wherein, in case of activation of more than one keys constituting one alphabetical character, activation of the first key is followed by activation of other remaining keys in sequence.
